(19) United States
(12) Patent Application Publication
(10) Pub. No.: US 2026/0252777 A1
(43) Pub. Date: Aug. 27, 2026

(54) VIRTUAL MAGNETIC CORE CONSTRUCTED BASED ON VECTOR MAGNETIC CIRCUIT PRINCIPLE AND APPLICATION METHOD THEREFOR

(71) Applicant: SOUTHEAST UNIVERSITY, Nanjing (CN)

(72) Inventors: Ming CHENG, Nanjing (CN); Wei QIN, Nanjing (CN); Zhejun LUO, Nanjing (CN); Wei HUA, Nanjing (CN); Zheng WANG, Nanjing (CN); Xinkai ZHU, Nanjing (CN)

(21) Appl. No.: 19/531,551

(22) Filed: Feb. 5, 2026

Related U.S. Application Data
(63) Continuation of application No. PCT/CN2025/082323, filed on Mar. 13, 2025.

(30) Foreign Application Priority Data
Feb. 25, 2025 (CN) 202510206153.X

(51) Int. Cl. G06F 30/392

(52) U.S. Cl. CPC G06F 30/392

(57) ABSTRACT

A magnetic core (iron core) is a crucial component of electromagnetic devices including motors, transformers, and reactors, accounting for approximately 50% of the total weight. In electromagnetic devices like air-core transformers, the magnetic core is absent. However, due to the poor magnetic permeability of air, a large excitation current is required, resulting in weak load capacity, bulky size, and limited application scope. According to the present disclosure, a plurality of vector magnetic circuit components are utilized to construct a virtual magnetic circuit with magnetic permeability similar to or even better than that of a physical magnetic core, constituting a virtual magnetic core. Based on this, an application method is provided for constructing electromagnetic devices, including transformers, reactors, and motors, using the virtual magnetic core, which is capable of achieving significant reductions in the weight and volume of such devices.

### CROSS-REFERENCE TO RELATED APPLICATIONS

This application is a continuation of PCT/CN2025/082323, filed on Mar. 13, 2025 and claims priority of Chinese Patent Application No. 202510206153.X, filed on Feb. 25, 2025, the entire contents of which are incorporated herein by reference.

### TECHNICAL FIELD

The present disclosure belongs to the field of magnetic circuit theory applications, and more specifically relates to magnetic circuit design for electromagnetic devices.

### BACKGROUND

The magnetic core (iron core), serving as the carrier of the magnetic circuit, provides a well-defined and predictable path for magnetic flux, effectively concentrating and guiding magnetic field energy. It is an indispensable and critical component in electromagnetic devices such as transformers, reactors, and motors, and is widely used in large quantities. For ease of description, the term “magnetic core” is uniformly adopted throughout the present disclosure. According to High-frequency Magnetic Components (Second Edition) by Kazimierczuk M. K., there are currently two main types of magnetic core constructions.

The first is the conventional magnetic core, which is made of high-permeability materials such as metal laminations, powdered materials, or ferrites, and is capable of forming a complete closed magnetic circuit. This type of core exhibits high magnetic permeability, effectively confines magnetic flux, reduces leakage flux, and thereby significantly lowers magnetic circuit losses while improving system efficiency and stability. However, conventional magnetic cores also have drawbacks: the conventional magnetic cores typically account for 50% to 70% of the effective material weight in electromagnetic devices, are subject to saturation effects leading to nonlinear magnetic characteristics, and tend to generate core losses under alternating magnetic fields, resulting in heat buildup that necessitates additional cooling measures.

The second type is the air core, which forms a closed magnetic circuit through air or other gaseous media and is commonly used in high-frequency converters and other high-frequency electromagnetic equipment. The air core offers low magnetic permeability, making it suitable for low-loss and high-frequency applications and helping to reduce energy loss in the magnetic circuit. However, due to its inability to precisely control the magnetic flux path, it suffers from significant flux leakage and lower energy conversion efficiency. Its performance is generally inferior to that of conventional magnetic cores, and therefore, its application scenarios remain relatively limited.

According to Chinese patents CN202011350276.4 and CN202311372958.9, and based on vector magnetic circuit theory, the performance of a magnetic core is determined by three fundamental magnetic circuit parameters: reluctance, magductance, and hysteretance. By introducing additional magnetic circuit components, these parameters can be effectively adjusted, thereby achieving the regulation of magnetic core performance. Currently, research on magnetic cores primarily focuses on the design and improvement of conventional magnetic cores and air cores. Once a magnetic core is manufactured and placed into stable operation, its magnetic circuit parameters are generally fixed, making it difficult to adjust or optimize the characteristics of the magnetic core. Therefore, how to innovate magnetic core design through the addition of external magnetic circuit components (e.g., magductance components), thereby creating entirely new types of magnetic cores and effectively improving various performance metrics of the magnetic circuit, such as power, efficiency, and coupling coefficient, has not yet been sufficiently studied or resolved.

### SUMMARY

Technical problem: in view of the drawbacks of the background art, the present disclosure provides a virtual magnetic core constructed based on a vector magnetic circuit principle and an application method therefor. The vector magnetic circuit principle is utilized to construct a virtual magnetic circuit from a plurality of vector magnetic circuit components. This virtual magnetic circuit exhibits magnetic permeability comparable to or better than that of a physical magnetic core, thereby forming the virtual magnetic core. Through reasonable configuration and parameter adjustment of each vector magnetic circuit component, engineered design and online adjustment of the magnetic circuit parameters of the virtual magnetic core can be achieved. This achievement can provide effective control over the amplitude and phase of magnetic flux within the magnetic circuit, thereby regulating its power and optimizing overall performance. Based on this, an application method is provided for constructing electromagnetic devices, including transformers, reactors, and motors, using the virtual magnetic core, which is capable of achieving significant reductions in the weight and volume of such devices.

Technical solution: to solve the above technical problems, the present disclosure provides a virtual magnetic core constructed based on a vector magnetic circuit principle, including: a magnetic flux loop coupled with a plurality of vector magnetic circuit components and a plurality of excitation windings to collectively form a virtual magnetic circuit, thereby constituting the virtual magnetic core, in which the virtual magnetic core is configured to partially or entirely replace a conventional magnetic core; and by configuring circuit components connected to each vector magnetic circuit component, magnetic circuit parameters of the virtual magnetic core are adjusted, amplitude and phase of magnetic flux in the magnetic circuit are controlled, excitation current of the magnetic circuit is regulated, and active power and reactive power of the magnetic circuit are affected; and

each vector magnetic circuit component forming the virtual magnetic core includes: a magductance-closed coil and a capacitive component connected thereto, thereby providing the vector magnetic circuit component with negative reluctance and positive magductance; according to a vector magnetic circuit theory, an equivalent magnetic circuit impedance of each vector magnetic circuit component under sinusoidal excitation is expressed as:

$$𝒵 = - \frac{{N}^{2} {ω}^{2} C}{1 + {( ω CR )}^{2}} + j \frac{{N}^{2} {ω}^{3} {C}^{2} R}{1 + {( ω CR )}^{2}} ,$$

where [symbol] represents an equivalent magnetic impedance of the vector magnetic circuit component, N represents a number of turns of the magductance-closed coil, ω represents an angular frequency of a magnetomotive force, C represents a capacitance value of the capacitive component, and R represents a resistance value of the magductance-closed coil; and a magnetic impedance of each vector magnetic circuit component includes a negative reluctance term and a positive magductance term, and the negative reluctance term is configured to partially or fully offset an air magnetic reluctance of a target magnetic circuit. If the magductance-closed coil is made of superconducting material with approximately zero resistance R, the positive magductance term is eliminated.

Each vector magnetic circuit component forming the virtual magnetic core includes: a magductance-closed coil, and an active circuit component with negative resistance connected thereto, causing the magnetic circuit component to exhibit negative magductance; under operation, an equivalent magnetic reactance of each vector magnetic circuit component is given by:

$$𝒳 = \frac{ω {N}^{2}}{- R} ,$$

where χ represents an equivalent magnetic reactance of the vector magnetic circuit component, N represents a number of turns of the magductance-closed coil, and −R represents a sum of a resistance value of the magductance-closed coil and an equivalent negative resistance value of the active circuit component; and a magnetic impedance of each vector magnetic circuit component constitutes a negative magnetic reactance term, which is configured to partially or fully offset a positive magnetic reactance, thereby making the overall magnetic impedance of the magnetic circuit approximately equal to or less than that of a physical magnetic core.

The vector magnetic circuit components within the virtual magnetic core are arranged along a direction of magnetic flux in various configurations, including series, parallel, cascade, or spatially nested structures. Different arrangement patterns of the vector magnetic circuit components correspond to different magnetic circuit parameters. Furthermore, in practical applications, the arrangement patterns of the vector magnetic circuit components exert distinct influences on various magnetic circuit variables, such as magnetomotive force and magnetic flux.

The vector magnetic circuit components within the virtual magnetic core are configured in a plurality of geometries and winding configurations including rectangular, circular, polygonal, and concentric structures, with different winding patterns and turn numbers, in accordance with design requirements. Different geometric topologies and winding configurations of the vector magnetic circuit components are selected such that different equivalent magnetic circuit parameters are imparted to the magnetic circuit. Furthermore, in practical applications, the specific topological structure and spatial arrangement of these components exert varying influences on magnetic circuit variables, including magnetomotive force and magnetic flux.

The geometric shape, spatial arrangement, size, as well as the type and number of required vector magnetic circuit components of the virtual magnetic core are determined by practical application needs. (For example, if six vector magnetic circuit components are to be placed along the magnetic circuit, the vector magnetic circuit components may be arranged in groups of three and three, two-two-two, or three-two-one, etc. The specific arrangement and its resulting effect depend on the user's actual requirements.)

The present disclosure provides an application method for the virtual magnetic core constructed based on a vector magnetic circuit principle, including: forming an electromagnetic device operating via an alternating magnetic field using the virtual magnetic core and at least one conductor coil, in which the electromagnetic device includes a reactor, a transformer, and a motor.

For a target magnetic circuit to which the method is applied, the method is implemented to reduce, as far as possible, a magnetic impedance and an excitation current (magnetomotive force) of the target magnetic circuit under a preset target magnetic flux condition, specifically as follows:
S1, calculating magnetic circuit parameters of the target magnetic circuit without the virtual magnetic core, based on a physical structure and actual operating conditions of the target magnetic circuit including frequency and temperature, where the magnetic circuit parameters include magnetic flux, magnetic reluctance, and magnetic reactance;
S2, determining a specific application form for the virtual magnetic core, including partial or complete replacement; determining a number and positions of vector magnetic circuit components within the virtual magnetic core based on the calculated magnetic circuit parameters; and calculating magnetic circuit parameters of the vector magnetic circuit components;
S3, introducing the configured vector magnetic circuit components into the target magnetic circuit to construct the virtual magnetic core; and
S4, counteracting positive magnetic circuit parameters in the target magnetic circuit using negative magnetic circuit parameters, including negative reluctance and negative magductance, of the vector magnetic circuit components within the virtual magnetic core, without affecting normal device operation; and continuously adjusting a configuration of the vector magnetic circuit components within the virtual magnetic core to optimize magnetic impedance characteristics of the target magnetic circuit, thereby ensuring that the excitation current, i.e., the magnetomotive force, of the target magnetic circuit is minimized under the preset target magnetic flux condition, and causing the virtual magnetic core to match or surpass a physical magnetic core in key performance metrics.

The method is applicable to any magnetic core capable of forming a closed magnetic circuit, and no specific limitation is imposed on physical attributes of the target magnetic circuit including shape, material, or structure.

Magnetic circuit parameters of the selected vector magnetic circuit components are either time-invariant or time-variant. No limitation is imposed on the specific form of the magnetic circuit parameters, provided that the application of these parameters does not affect the normal operation of the target magnetic circuit. (Time-invariant magnetic circuit parameters refer to those that do not change over time, typically achievable with materials such as metallic conductors; and time-variant parameters are those that change over time, often realizable with materials like superconductors.)

Further, the application method for the virtual magnetic core provided by the present disclosure is applicable to any electromagnetic device containing a magnetic circuit structure, including but not limited to reactors, transformers, and motors. Additionally, no specific limitation is imposed on the physical attributes of the target magnetic circuit, such as its shape, material, or structure.

Beneficial effects: compared to the related art, the technical solutions of the present disclosure have the following beneficial effects.

1. The virtual magnetic core and the application method therefor designed in the present disclosure differ from conventional magnetic cores and air cores, innovatively providing a scheme for constructing a virtual magnetic core. While ensuring that magnetic circuit performance remains unaffected, the virtual magnetic core is configured to partially or completely replace conventional magnetic cores or air cores, thereby adjusting magnetic circuit parameters, controlling the amplitude and phase of magnetic flux in the circuit, regulating the excitation current (magnetomotive force) of the circuit, optimizing the distribution of active and reactive power, improving the power-to-weight ratio of electromagnetic devices, and enhancing the overall performance of the magnetic circuit.

2. The virtual magnetic core and the application method therefor designed in the present disclosure are characterized in that the virtual magnetic core includes a plurality of vector magnetic circuit components solely. Compared with conventional magnetic cores, this structure significantly reduces the overall weight of the magnetic core and overcomes issues associated with conventional cores, such as being prone to saturation, high losses, significant heat generation, and difficulties in heat dissipation. Furthermore, the structural features of the virtual magnetic core allow it to be easily folded, packed, and transported, facilitating efficient circulation and use in practical applications.

3. The virtual magnetic core and the application method therefor designed in the present disclosure are characterized in that the magnetic flux path of the virtual magnetic core can be flexibly planned according to practical needs, and its magnetic circuit parameters can be adjusted online, thereby significantly enhancing the flexibility and degree of freedom in magnetic core design. Compared with air cores, under the same target magnetic flux condition, the virtual magnetic core requires a lower excitation current and achieves higher transmission efficiency, while maintaining stable electromagnetic coupling and lower flux leakage.

### BRIEF DESCRIPTION OF THE DRAWINGS

FIG. 1 is a schematic diagram of a virtual magnetic core according to the present disclosure.

FIG. 2A is a schematic diagram of a closed magnetic circuit consisting of the virtual magnetic core.

FIG. 2B is a schematic diagram of a closed magnetic circuit formed by the virtual magnetic core and a conventional magnetic core.

FIG. 3A is a schematic diagram of a vector magnetic circuit component including a magductance component and a capacitive component.

FIG. 3B is a schematic diagram of a vector magnetic circuit component having negative reluctance and positive magnetance, and an equivalent magnetic circuit diagram thereof.

FIG. 4A is a schematic diagram of a vector magnetic circuit component including a magductance component and an active circuit component.

FIG. 4B is a schematic diagram of a vector magnetic circuit component characterized by negative magnetic reactance, and an equivalent magnetic circuit diagram thereof.

FIG. 5A is a schematic diagram of a circular winding configuration of a vector magnetic circuit component within the virtual magnetic core.

FIG. 5B is a schematic diagram of a rectangular winding configuration of a vector magnetic circuit component within the virtual magnetic core.

FIG. 5C is a schematic diagram of a polygonal winding configuration of a vector magnetic circuit component within the virtual magnetic core.

FIG. 5D is a schematic diagram of a concentric winding configuration of a vector magnetic circuit component within the virtual magnetic core.

FIG. 6 is a flow chart of an application method for the virtual magnetic core according to the present disclosure.

FIG. 7 is a schematic diagram of the application method for the virtual magnetic core according to the present disclosure.

FIG. 8 is a schematic diagram showing the primary-side voltage, secondary-side voltage, and excitation current of a circuit without the virtual magnetic core according to the present disclosure.

FIG. 9 is a schematic diagram showing the primary-side voltage, secondary-side voltage, and excitation current of a circuit with a negative reluctance vector magnetic circuit component added, according to the present disclosure.

FIG. 10 is a schematic diagram showing the primary-side voltage, secondary-side voltage, and excitation current of a circuit with a negative-magductance vector magnetic circuit component added, according to the present disclosure.

FIG. 11 is a schematic diagram showing waveforms of the primary-side voltage, secondary-side voltage, and excitation current for the virtual magnetic core under a 10Ω load, according to the present disclosure.

FIG. 12 is a schematic diagram showing waveforms of the primary-side voltage, secondary-side voltage, and excitation current for a conventional magnetic core under a 10Ω load, according to the present disclosure.

### DETAILED DESCRIPTION

To make the objectives, technical solutions, and advantages of the present disclosure more apparent, the technical solutions of the present disclosure are further described in detail with reference to accompanying drawings. Obviously, the specific embodiments described herein are intended merely to explain the present disclosure, rather than limiting the present disclosure.

It is to be understood by those skilled in the art that, unless otherwise defined, all terms (including technical and scientific terms) used herein have the same meaning as commonly understood by one of ordinary skill in the art to which the present disclosure belongs. It is to be further understood that terms, such as those defined in commonly used dictionaries, are to be interpreted as having meanings consistent with the meanings of the terms in the context of the relevant art and are not to be construed in an idealized or overly formal sense unless explicitly defined as such herein.

The magnetic core, serving as the carrier of the magnetic circuit, can not only provide a well-defined and predictable path for magnetic flux but also effectively concentrate and guide magnetic field energy. Currently, magnetic cores are mainly divided into two categories. The first category includes conventional magnetic cores, which serve as essential components in electromagnetic devices such as motors, transformers, and reactors.

The second category is air cores, whose magnetic flux paths rely on air or other gaseous media to form a closed loop. Air cores are not subject to magnetic saturation and offer relatively good heat dissipation characteristics. However, electromagnetic devices such as air-core transformers lack a magnetic core, which prevents effective planning of the magnetic flux path. Whether for conventional magnetic cores or air cores, once manufactured and placed in a stable operating environment, the magnetic circuit parameters become fixed, making it difficult to achieve online adjustment of the magnetic core performance.

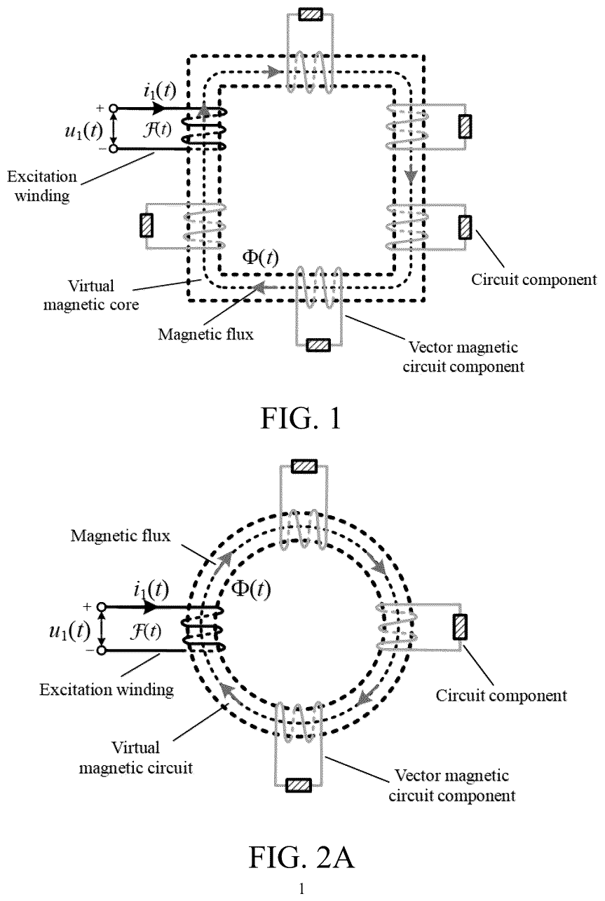

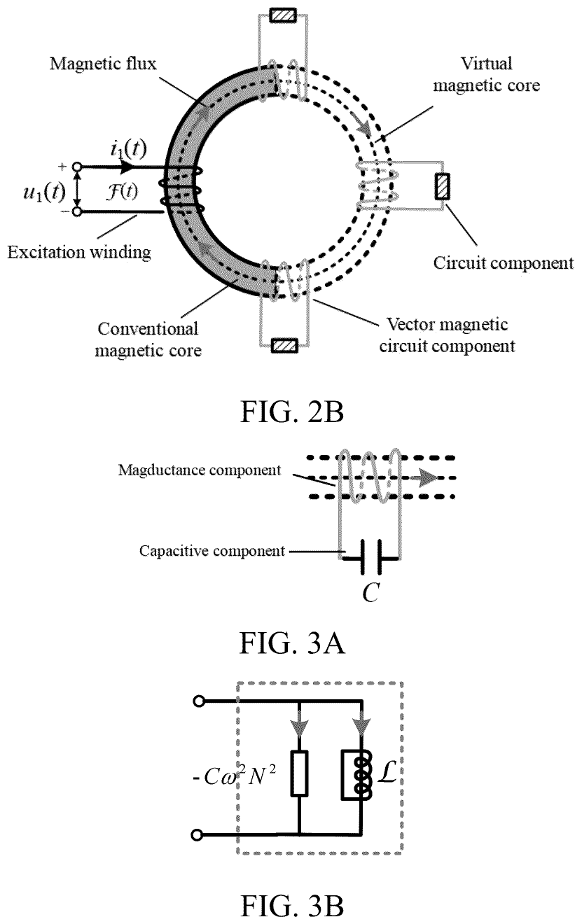

To solve the above problems, the present disclosure provides a virtual magnetic core constructed based on a vector magnetic circuit principle. As shown in FIG. 1 and FIGS. 2A and 2B, a plurality of vector magnetic circuit components are utilized to construct a virtual magnetic circuit, which can partially or completely replace a conventional magnetic core or an air core to form a closed magnetic circuit. Its magnetic permeability is comparable to or even better than that of a physical magnetic core, thereby forming the virtual magnetic core. By reasonably circuit components connected to each vector magnetic circuit component, magnetic circuit parameters of the virtual magnetic core can be adjusted, amplitude and phase of magnetic flux in the magnetic circuit can be controlled, excitation current (magnetomotive force) of the magnetic circuit can be regulated, and active power and reactive power of the magnetic circuit can be affected.

Furthermore, each vector magnetic circuit component forming the virtual magnetic core includes: a magductance-closed coil and a capacitive component connected thereto, thereby providing the vector magnetic circuit component with negative reluctance and positive magductance, as shown in FIGS. 3A and 3B. According to a vector magnetic circuit theory, an equivalent magnetic circuit impedance of each vector magnetic circuit component under sinusoidal excitation is expressed as:

$$𝒵 = - \frac{{N}^{2} {ω}^{2} C}{1 + {( ω CR )}^{2}} + j \frac{{N}^{2} {ω}^{3} {C}^{2} R}{1 + {( ω CR )}^{2}} ,$$

where [symbol] represents an equivalent magnetic impedance of the vector magnetic circuit component, N represents a number of turns of the magductance-closed coil, ω represents an angular frequency of a magnetomotive force, C represents a capacitance value of the capacitive component, and R represents a resistance value of the magductance-closed coil. A magnetic impedance of each vector magnetic circuit component includes a negative reluctance term and a positive magnetance term, and the negative reluctance term is configured to partially or fully offset an air magnetic reluctance of a target magnetic circuit.

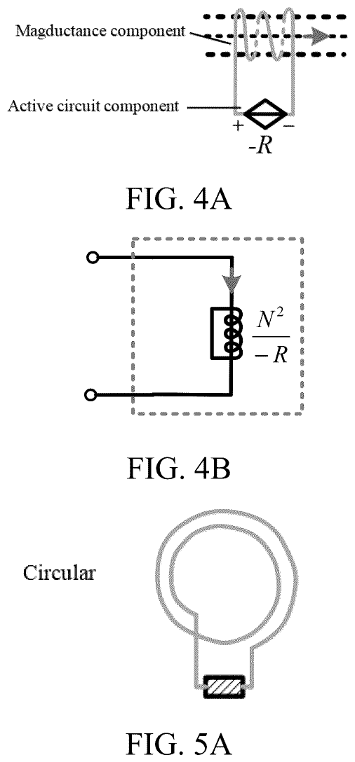

Furthermore, each vector magnetic circuit component forming the virtual magnetic core includes: a magductance-closed coil, and an active circuit component with negative resistance connected thereto, as shown in FIGS. 4A and 4B. The magnetic circuit component exhibits negative magductance. Under operation, an equivalent magnetic reactance of each vector magnetic circuit component is given by:

$$𝒳 = \frac{ω {N}^{2}}{- R} ,$$

where χ represents an equivalent magnetic reactance of the vector magnetic circuit component, N represents a number of turns of the magductance-closed coil, and −R represents a sum of a resistance value of the magductance-closed coil and an equivalent negative resistance value of the active circuit component. A magnetic impedance of each vector magnetic circuit component constitutes a negative magnetic reactance term, which is configured to partially or fully offset a positive magnetic reactance, thereby making the overall magnetic impedance of the magnetic circuit approximately equal to or less than that of a physical magnetic core.

Furthermore, the vector magnetic circuit components within the virtual magnetic core are arranged along a direction of magnetic flux in various configurations, including series, parallel, cascade, or even spatially nested structures. Different arrangement patterns of the vector magnetic circuit components correspond to different magnetic circuit parameters. Through the specific configurations, distinct influences are exerted on various magnetic circuit variables.

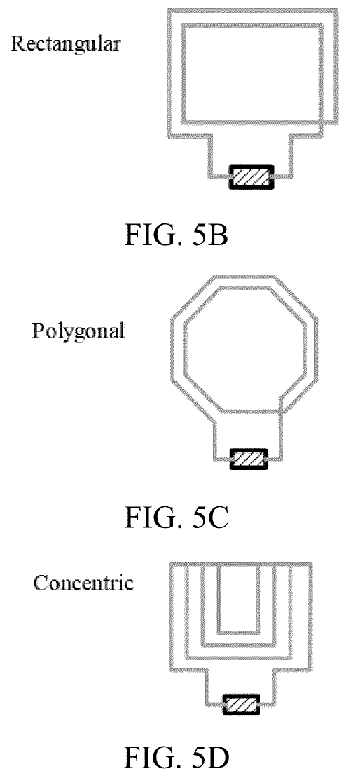

Furthermore, the vector magnetic circuit components within the virtual magnetic core can adopt different winding configurations and turn arrangements according to design requirements, such as rectangular, circular, polygonal, and concentric structures, as shown in FIGS. 5A, 5B, 5C, and 5D. Different geometric topologies and winding configurations of the vector magnetic circuit components are selected such that different equivalent magnetic circuit parameters are imparted to the magnetic circuit. Through the specific topological structure and spatial arrangement, varying influences are exerted on magnetic circuit variables, including magnetomotive force and magnetic flux.

Furthermore, the geometric shape, size, as well as the type and number of required vector magnetic circuit components of the virtual magnetic core are determined by practical application needs, as shown in FIGS. 2A and 2B.

Additionally, to solve the above technical problems, the present disclosure employs the following technical solutions.

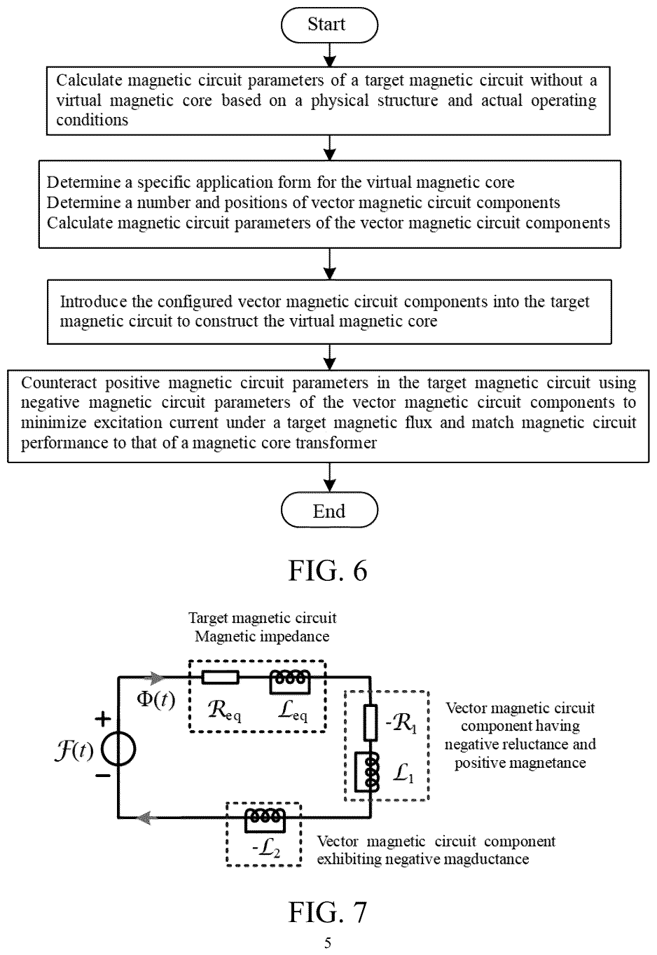

The present disclosure provides an application method for the virtual magnetic core. As shown in FIG. 6, the application method is carried out by forming an electromagnetic device, selected from a reactor, a transformer, and a motor, operating via an alternating magnetic field using the virtual magnetic core and at least one conductor coil.

Furthermore, according to the above application method for the virtual magnetic core, the following steps are performed for a target magnetic circuit to minimize its magnetic impedance and reduce the excitation current (magnetomotive force) under a preset target magnetic flux condition. A schematic diagram of the underlying principle is shown in FIG. 7, with details as follows:

In S1, based on a physical structure and actual operating conditions such as frequency and temperature of the target magnetic circuit including frequency and temperature, magnetic circuit parameters of the target magnetic circuit without the virtual magnetic core are calculated. The magnetic circuit parameters include magnetic flux, magnetic reluctance, and magnetic reactance.

In S2, a specific application form is determined for the virtual magnetic core, including partial or complete replacement. Based on the calculated magnetic circuit parameters, a number and positions of vector magnetic circuit components within the virtual magnetic core are determined, and magnetic circuit parameters of these vector magnetic circuit components are calculated.

In S3, the configured vector magnetic circuit components are introduced into the target magnetic circuit to construct the virtual magnetic core.

In S4, without affecting normal device operation, positive magnetic circuit parameters in the target magnetic circuit are progressively counteracted using negative magnetic circuit parameters (such as negative reluctance and negative magductance) of the vector magnetic circuit components within the virtual magnetic core. A configuration of the vector magnetic circuit components within the virtual magnetic core is continuously adjusted to optimize magnetic impedance characteristics of the target magnetic circuit, thereby ensuring that the excitation current (the magnetomotive force) of the target magnetic circuit is minimized under the preset target magnetic flux condition, and causing the virtual magnetic core to reach or surpass a physical magnetic core in key performance metrics.

Furthermore, in the application method for the virtual magnetic core provided by the present disclosure and as described in step S1, the method is applicable to any magnetic core capable of forming a closed magnetic circuit, and no specific limitation is imposed on physical attributes of the target magnetic circuit including shape, material, or structure.

Furthermore, in the application method for the virtual magnetic core provided by the present disclosure and as described in step S3, magnetic circuit parameters of the selected vector magnetic circuit components may be time-invariant (e.g., implemented with metallic conductors) or time-variant (e.g., implemented with superconducting materials). No limitation is imposed on the specific form of the magnetic circuit parameters, provided that the application of these parameters does not affect the normal operation of the target magnetic circuit.

Further, the application method for the virtual magnetic core provided by the present disclosure is applicable to any electromagnetic device containing a magnetic circuit structure, including but not limited to reactors, transformers, and motors. Additionally, no specific limitation is imposed on the physical attributes of the target magnetic circuit, such as its shape, material, or structure.

Hereinafter, the virtual magnetic core constructed based on the vector magnetic circuit principle and the application method therefor provided by the present disclosure are validated. The above design scheme is implemented in practice, and the feasibility of the present disclosure is verified via an experimental setup specifically constructed for this purpose. The verification setup includes a signal generator, a power amplifier, a target magnetic circuit, a power analyzer, a waveform recorder, an inductance, capacitance, resistance (LCR) meter, a voltage differential probe, and a high-frequency current probe. During the experiment, the signal generator and power amplifier drive the excitation windings of both the virtual magnetic core and the conventional magnetic core, forming a closed magnetic circuit and generating alternating magnetic flux. The LCR meter is configured to measure the circuit parameters of the vector magnetic circuit components within the virtual magnetic core, while the voltage differential probe and high-frequency current probe are configured to capture the primary-side voltage, excitation current, and secondary-side voltage. The experimental data are recorded and analyzed by the power analyzer and waveform recorder. Based on the collected experimental data, the magnetic circuit parameters of the target magnetic circuit are calculated, thereby verifying the effectiveness and feasibility of the virtual magnetic core design and the application method therefor.

The objective of the experiment is to apply the virtual magnetic core constructed based on the vector magnetic circuit principle and the application method therefor as described in the present disclosure. The virtual magnetic core constructed based on the vector magnetic circuit principle is utilized to replace the air core in a transformer, thereby reducing the magnetic impedance of the target magnetic circuit, lowering the excitation current, enhancing the coupling capability of the target magnetic circuit, and minimizing the excitation current (magnetomotive force) of the target magnetic circuit. As a result, the virtual magnetic core transformer is expected to approach or surpass the conventional magnetic core transformer in key performance metrics, thereby verifying the feasibility and engineering application value of this patent in electromagnetic devices.

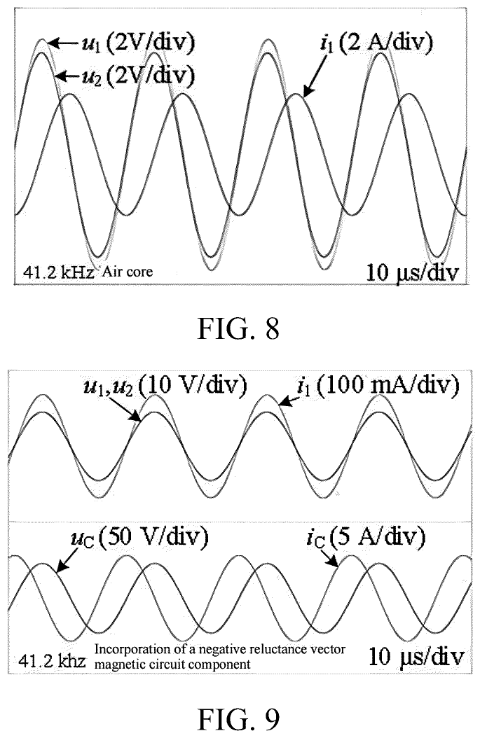

In the experiment, the target magnetic circuit is implemented using an air-core transformer. Both its primary-side and secondary-side windings are made of 0.1 mm×100 Litz wire and wound in a bifilar parallel arrangement on an EC90-specification core bobbin, with each winding having 23 turns. Under no-load conditions, the primary-side voltage u₁, secondary-side voltage u₂, and excitation current i₁ of the air-core transformer are measured, as shown in FIG. 8, from which the magnetomotive force and magnetic flux of the air-core transformer can be calculated. Based on Kirchhoff's magnetomotive force law in vector magnetic circuit theory, the magnetic circuit is analyzed using the above measurement data, and the magnetic reluctance parameter of the circuit is calculated to be 7.85×10⁸ H⁻¹ at an operating frequency of 41.2 kHz.

Since the air-core transformer possesses only a magnetic reluctance parameter, a vector magnetic circuit component with negative reluctance is introduced into the target magnetic circuit to counteract the positive magnetic reluctance, thereby forming a virtual magnetic core as shown in FIG. 7. The magnetic circuit component is wound with 0.1 mm×400 Litz wire, has 43 turns, and is connected to a capacitor C=0.47 μF. At the operating frequency of 41.2 kHz, the magnetomotive force of the transformer reaches a minimum, at which point the primary-side voltage u₁, secondary-side voltage u₂, and excitation current i₁ are all in phase, as shown in FIG. 9. When the secondary-side voltage u₂ is 45.14 V, the primary-side voltage u₁ is 45.54 V, the excitation current i₁ is 0.334 A, the voltage across the magnetic circuit component uc is 113.1 V, and its current i_{c} is 14.25 A, the coupling coefficient of the transformer is increased to 0.990. Under these conditions, the power factor of the transformer reaches 0.999, indicating that its magnetic reluctance parameter has been effectively reduced to zero. However, the introduced magnetic circuit component also generates a magnetic reactance parameter with a value of 1.00×10⁷ H⁻¹, which confirms the validity of FIG. 7.

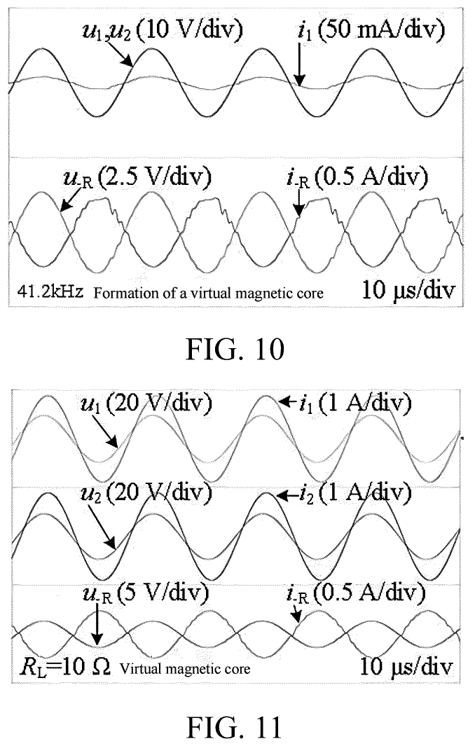

Since the target magnetic circuit still exhibits a positive magnetic reactance parameter at this stage, to further optimize the magnetic circuit performance, a magnetic circuit component with a negative magductance parameter is added to the constructed virtual magnetic core, as shown in FIG. 7. Specifically, two negative-magductance magnetic circuit components, each wound with Dupont wire and having 2 turns, are introduced into the virtual magnetic core, with an equivalent negative resistance value of −5.8Ω. After incorporating these components, as shown in FIG. 10 and under the same secondary-side voltage u₂ condition, the excitation current i₁ drops to 20 mA, and the magnetic impedance of the circuit is reduced to 6.07×10⁴ H⁻¹ thereby achieving minimization of the excitation current (magnetomotive force). This result verifies the effectiveness and feasibility of the virtual magnetic core constructed based on the vector magnetic circuit principle and the application method therefor provided in the present disclosure.

To further verify the effectiveness of the virtual magnetic core, the magnetic circuit performance of transformers using a conventional magnetic core is compared with that of transformers using the virtual magnetic core. The conventional magnetic core includes a pair of EC90-size PC40 ferrite cores with a mass of 660 g, whereas the transformer employing the virtual magnetic core has a total mass of 270 g. Within this total, the primary-side and secondary-side windings together with the winding bobbin account for 52 g, and the additional vector magnetic circuit components contribute 218 g. Compared with the conventional magnetic core, the virtual magnetic core transformer achieves a mass reduction of 59.1%, realizing a lightweight design of the transformer.

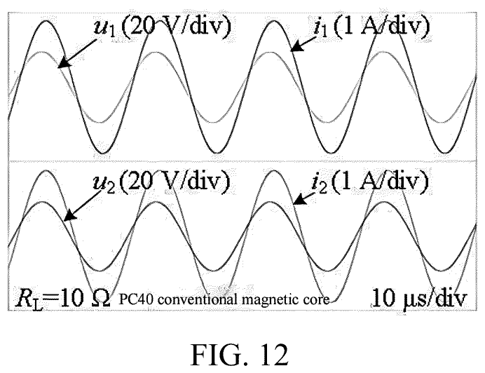

FIGS. 11 and 12 show the waveforms of the primary-side voltage u₁, excitation current i₁, secondary-side voltage u₂, and load current i₂ for the transformer with the conventional magnetic core and the virtual magnetic core, respectively. The results demonstrate that the virtual magnetic core can not only achieve magnetic circuit performance comparable to that of the conventional magnetic core but also significantly reduce the weight and volume of the electromagnetic device, further verifying the effectiveness and feasibility of the virtual magnetic core constructed based on the vector magnetic circuit principle and the application method therefor.

In summary, the present disclosure provides a virtual magnetic core constructed based on a vector magnetic circuit principle and an application method therefor. The foregoing presents preferred embodiments of the present disclosure. The scope of protection, however, is not limited thereto. The target magnetic circuit is not confined to transformers but extends to any electromagnetic device incorporating a closed magnetic circuit. Equivalent modifications or variations made by those skilled in the art based on the content revealed by the present disclosure also fall under the protection defined by the claims.

The foregoing is only part of the embodiments of the present disclosure. It is to be noted that a person of ordinary skill in the art may make several improvements and embellishments without departing from the principle of the present disclosure, and these improvements and embellishments are regarded as falling within the scope of protection of the present disclosure.

1. A virtual magnetic core constructed based on a vector magnetic circuit principle, comprising: a magnetic flux loop coupled with a plurality of vector magnetic circuit components and a plurality of excitation windings to collectively form a virtual magnetic circuit, constituting the virtual magnetic core, wherein the virtual magnetic core is configured to partially or entirely replace a conventional magnetic core; and by configuring circuit components connected to each vector magnetic circuit component, magnetic circuit parameters of the virtual magnetic core are adjusted, amplitude and phase of magnetic flux in the magnetic circuit are controlled, excitation current of the magnetic circuit is regulated, and active power and reactive power of the magnetic circuit are affected; and
each vector magnetic circuit component forming the virtual magnetic core comprises: a magductance-closed coil and a capacitive component connected thereto, providing the vector magnetic circuit component with negative reluctance and positive magductance; under sinusoidal excitation, an equivalent magnetic circuit impedance of each vector magnetic circuit component is expressed as:
$$𝒵 = - \frac{{N}^{2} {ω}^{2} C}{1 + {( ω CR )}^{2}} + j \frac{{N}^{2} {ω}^{3} {C}^{2} R}{1 + {( ω CR )}^{2}} ,$$
where [symbol] represents an equivalent magnetic impedance of the vector magnetic circuit component, N represents a number of turns of the magductance-closed coil, ω represents an angular frequency of a magnetomotive force, C represents a capacitance value of the capacitive component, and R represents a resistance value of the magductance-closed coil; and a magnetic impedance of each vector magnetic circuit component comprises a negative reluctance term and a positive magductance term, and the negative reluctance term is configured to partially or fully offset an air magnetic reluctance of a target magnetic circuit.

2. A virtual magnetic core constructed based on a vector magnetic circuit principle, comprising: a magnetic flux loop coupled with a plurality of vector magnetic circuit components and a plurality of excitation windings to collectively form a virtual magnetic circuit, constituting the virtual magnetic core, wherein the virtual magnetic core is configured to partially or entirely replace a conventional magnetic core; and by configuring circuit components connected to each vector magnetic circuit component, magnetic circuit parameters of the virtual magnetic core are adjusted, amplitude and phase of magnetic flux in the magnetic circuit are controlled, excitation current of the magnetic circuit is regulated, and active power and reactive power of the magnetic circuit are affected; and
each vector magnetic circuit component forming the virtual magnetic core comprises: a magductance-closed coil, and an active circuit component with negative resistance connected thereto, causing the magnetic circuit component to exhibit negative magductance; under operation, an equivalent magnetic reactance of each vector magnetic circuit component is given by:
$$𝒳 = \frac{ω {N}^{2}}{- R} ,$$
where χ represents an equivalent magnetic reactance of the vector magnetic circuit component, N represents a number of turns of the magductance-closed coil, and −R represents a sum of a resistance value of the magductance-closed coil and an equivalent negative resistance value of the active circuit component; and a magnetic impedance of each vector magnetic circuit component constitutes a negative magnetic reactance term.

3. The virtual magnetic core constructed based on a vector magnetic circuit principle according to claim 1, wherein the vector magnetic circuit components within the virtual magnetic core are arranged along a direction of magnetic flux in various configurations, comprising series, parallel, cascade, or spatially nested structures.

4. The virtual magnetic core constructed based on a vector magnetic circuit principle according to claim 2, wherein the vector magnetic circuit components within the virtual magnetic core are arranged along a direction of magnetic flux in various configurations, comprising series, parallel, cascade, or spatially nested structures.

5. The virtual magnetic core constructed based on a vector magnetic circuit principle according to claim 1, wherein the vector magnetic circuit components within the virtual magnetic core are configured in a plurality of geometries and winding configurations comprising rectangular, circular, polygonal, and concentric structures, with different winding patterns and turn numbers, in accordance with design requirements; and different geometric topologies and winding configurations of the vector magnetic circuit components are selected such that different equivalent magnetic circuit parameters are imparted to the magnetic circuit.

6. The virtual magnetic core constructed based on a vector magnetic circuit principle according to claim 2, wherein the vector magnetic circuit components within the virtual magnetic core are configured in a plurality of geometries and winding configurations comprising rectangular, circular, polygonal, and concentric structures, with different winding patterns and turn numbers, in accordance with design requirements; and different geometric topologies and winding configurations of the vector magnetic circuit components are selected such that different equivalent magnetic circuit parameters are imparted to the magnetic circuit.

7. An application method for the virtual magnetic core constructed based on a vector magnetic circuit principle according to claim 1, comprising: forming an electromagnetic device operating via an alternating magnetic field using the virtual magnetic core and at least one conductor coil, wherein the electromagnetic device comprises a reactor, a transformer, and a motor.

8. An application method for the virtual magnetic core constructed based on a vector magnetic circuit principle according to claim 2, comprising: forming an electromagnetic device operating via an alternating magnetic field using the virtual magnetic core and at least one conductor coil, wherein the electromagnetic device comprises a reactor, a transformer, and a motor.

9. An application method for the virtual magnetic core constructed based on a vector magnetic circuit principle according to claim 3, comprising: forming an electromagnetic device operating via an alternating magnetic field using the virtual magnetic core and at least one conductor coil, wherein the electromagnetic device comprises a reactor, a transformer, and a motor.

10. An application method for the virtual magnetic core constructed based on a vector magnetic circuit principle according to claim 4, comprising: forming an electromagnetic device operating via an alternating magnetic field using the virtual magnetic core and at least one conductor coil, wherein the electromagnetic device comprises a reactor, a transformer, and a motor.

11. An application method for the virtual magnetic core constructed based on a vector magnetic circuit principle according to claim 5, comprising: forming an electromagnetic device operating via an alternating magnetic field using the virtual magnetic core and at least one conductor coil, wherein the electromagnetic device comprises a reactor, a transformer, and a motor.

12. An application method for the virtual magnetic core constructed based on a vector magnetic circuit principle according to claim 6, comprising: forming an electromagnetic device operating via an alternating magnetic field using the virtual magnetic core and at least one conductor coil, wherein the electromagnetic device comprises a reactor, a transformer, and a motor.

13. The application method for the virtual magnetic core constructed based on a vector magnetic circuit principle according to claim 7, wherein for a target magnetic circuit, the method is implemented to reduce a magnetic impedance and an excitation current of the target magnetic circuit under a preset target magnetic flux condition, specifically as follows:
S1, calculating magnetic circuit parameters of the target magnetic circuit without the virtual magnetic core, based on a physical structure and actual operating conditions of the target magnetic circuit comprising frequency and temperature, wherein the magnetic circuit parameters comprise magnetic flux, magnetic reluctance, and magnetic reactance;
S2, determining a specific application form for the virtual magnetic core, comprising partial or complete replacement; determining a number and positions of vector magnetic circuit components within the virtual magnetic core based on the calculated magnetic circuit parameters; and calculating magnetic circuit parameters of the vector magnetic circuit components;
S3, introducing the configured vector magnetic circuit components into the target magnetic circuit to construct the virtual magnetic core; and
S4, counteracting positive magnetic circuit parameters in the target magnetic circuit using negative magnetic circuit parameters, comprising negative reluctance and negative magductance, of the vector magnetic circuit components within the virtual magnetic core, without affecting normal device operation; and continuously adjusting a configuration of the vector magnetic circuit components within the virtual magnetic core to optimize magnetic impedance characteristics of the target magnetic circuit, minimizing the excitation current of the target magnetic circuit.

14. The application method for the virtual magnetic core constructed based on a vector magnetic circuit principle according to claim 8, wherein for a target magnetic circuit, the method is implemented to reduce a magnetic impedance and an excitation current of the target magnetic circuit under a preset target magnetic flux condition, specifically as follows:
S1, calculating magnetic circuit parameters of the target magnetic circuit without the virtual magnetic core, based on a physical structure and actual operating conditions of the target magnetic circuit comprising frequency and temperature, wherein the magnetic circuit parameters comprise magnetic flux, magnetic reluctance, and magnetic reactance;
S2, determining a specific application form for the virtual magnetic core, comprising partial or complete replacement; determining a number and positions of vector magnetic circuit components within the virtual magnetic core based on the calculated magnetic circuit parameters; and calculating magnetic circuit parameters of the vector magnetic circuit components;
S3, introducing the configured vector magnetic circuit components into the target magnetic circuit to construct the virtual magnetic core; and
S4, counteracting positive magnetic circuit parameters in the target magnetic circuit using negative magnetic circuit parameters, comprising negative reluctance and negative magductance, of the vector magnetic circuit components within the virtual magnetic core, without affecting normal device operation; and continuously adjusting a configuration of the vector magnetic circuit components within the virtual magnetic core to optimize magnetic impedance characteristics of the target magnetic circuit, minimizing the excitation current of the target magnetic circuit.

15. The application method for the virtual magnetic core constructed based on a vector magnetic circuit principle according to claim 9, wherein for a target magnetic circuit, the method is implemented to reduce a magnetic impedance and an excitation current of the target magnetic circuit under a preset target magnetic flux condition, specifically as follows:
S1, calculating magnetic circuit parameters of the target magnetic circuit without the virtual magnetic core, based on a physical structure and actual operating conditions of the target magnetic circuit comprising frequency and temperature, wherein the magnetic circuit parameters comprise magnetic flux, magnetic reluctance, and magnetic reactance;
S2, determining a specific application form for the virtual magnetic core, comprising partial or complete replacement; determining a number and positions of vector magnetic circuit components within the virtual magnetic core based on the calculated magnetic circuit parameters; and calculating magnetic circuit parameters of the vector magnetic circuit components;
S3, introducing the configured vector magnetic circuit components into the target magnetic circuit to construct the virtual magnetic core; and
S4, counteracting positive magnetic circuit parameters in the target magnetic circuit using negative magnetic circuit parameters, comprising negative reluctance and negative magductance, of the vector magnetic circuit components within the virtual magnetic core, without affecting normal device operation; and continuously adjusting a configuration of the vector magnetic circuit components within the virtual magnetic core to optimize magnetic impedance characteristics of the target magnetic circuit, minimizing the excitation current of the target magnetic circuit.

16. The application method for the virtual magnetic core constructed based on a vector magnetic circuit principle according to claim 10, wherein for a target magnetic circuit, the method is implemented to reduce a magnetic impedance and an excitation current of the target magnetic circuit under a preset target magnetic flux condition, specifically as follows:
S1, calculating magnetic circuit parameters of the target magnetic circuit without the virtual magnetic core, based on a physical structure and actual operating conditions of the target magnetic circuit comprising frequency and temperature, wherein the magnetic circuit parameters comprise magnetic flux, magnetic reluctance, and magnetic reactance;
S2, determining a specific application form for the virtual magnetic core, comprising partial or complete replacement; determining a number and positions of vector magnetic circuit components within the virtual magnetic core based on the calculated magnetic circuit parameters; and calculating magnetic circuit parameters of the vector magnetic circuit components;
S3, introducing the configured vector magnetic circuit components into the target magnetic circuit to construct the virtual magnetic core; and
S4, counteracting positive magnetic circuit parameters in the target magnetic circuit using negative magnetic circuit parameters, comprising negative reluctance and negative magductance, of the vector magnetic circuit components within the virtual magnetic core, without affecting normal device operation; and continuously adjusting a configuration of the vector magnetic circuit components within the virtual magnetic core to optimize magnetic impedance characteristics of the target magnetic circuit, minimizing the excitation current of the target magnetic circuit.

17. The application method for the virtual magnetic core constructed based on a vector magnetic circuit principle according to claim 11, wherein for a target magnetic circuit, the method is implemented to reduce a magnetic impedance and an excitation current of the target magnetic circuit under a preset target magnetic flux condition, specifically as follows:
S1, calculating magnetic circuit parameters of the target magnetic circuit without the virtual magnetic core, based on a physical structure and actual operating conditions of the target magnetic circuit comprising frequency and temperature, wherein the magnetic circuit parameters comprise magnetic flux, magnetic reluctance, and magnetic reactance;
S2, determining a specific application form for the virtual magnetic core, comprising partial or complete replacement; determining a number and positions of vector magnetic circuit components within the virtual magnetic core based on the calculated magnetic circuit parameters; and calculating magnetic circuit parameters of the vector magnetic circuit components;
S3, introducing the configured vector magnetic circuit components into the target magnetic circuit to construct the virtual magnetic core; and
S4, counteracting positive magnetic circuit parameters in the target magnetic circuit using negative magnetic circuit parameters, comprising negative reluctance and negative magductance, of the vector magnetic circuit components within the virtual magnetic core, without affecting normal device operation; and continuously adjusting a configuration of the vector magnetic circuit components within the virtual magnetic core to optimize magnetic impedance characteristics of the target magnetic circuit, minimizing the excitation current of the target magnetic circuit.

18. The application method for the virtual magnetic core constructed based on a vector magnetic circuit principle according to claim 12, wherein for a target magnetic circuit, the method is implemented to reduce a magnetic impedance and an excitation current of the target magnetic circuit under a preset target magnetic flux condition, specifically as follows:
S1, calculating magnetic circuit parameters of the target magnetic circuit without the virtual magnetic core, based on a physical structure and actual operating conditions of the target magnetic circuit comprising frequency and temperature, wherein the magnetic circuit parameters comprise magnetic flux, magnetic reluctance, and magnetic reactance;
S2, determining a specific application form for the virtual magnetic core, comprising partial or complete replacement; determining a number and positions of vector magnetic circuit components within the virtual magnetic core based on the calculated magnetic circuit parameters; and calculating magnetic circuit parameters of the vector magnetic circuit components;
S3, introducing the configured vector magnetic circuit components into the target magnetic circuit to construct the virtual magnetic core; and
S4, counteracting positive magnetic circuit parameters in the target magnetic circuit using negative magnetic circuit parameters, comprising negative reluctance and negative magductance, of the vector magnetic circuit components within the virtual magnetic core, without affecting normal device operation; and continuously adjusting a configuration of the vector magnetic circuit components within the virtual magnetic core to optimize magnetic impedance characteristics of the target magnetic circuit, minimizing the excitation current of the target magnetic circuit.

19. The application method for the virtual magnetic core constructed based on a vector magnetic circuit principle according to claim 7, wherein the method is applicable to any magnetic core capable of forming a closed magnetic circuit, and no specific limitation is imposed on physical attributes of the target magnetic circuit comprising shape, material, spatial arrangement, or structure.

20. The application method for the virtual magnetic core constructed based on a vector magnetic circuit principle according to claim 7, wherein magnetic circuit parameters of the selected vector magnetic circuit components are either time-invariant or time-variant.
